(19) United States
(12) Patent Application Publication
(10) Pub. No.: US 2025/0336883 A1
(43) Pub. Date: Oct. 30, 2025

(54) APPARATUS AND BONDING PROCESS FOR WAFER BONDING

(71) Applicant: Taiwan Semiconductor Manufacturing Co., Ltd., Hsinchu (TW)

(72) Inventors: Guan-Ren Wang, Hsinchu (TW); Kuan-Kan Hu, Hsinchu (TW); Chun-Yu Liu, New Taipei City (TW); Ku-Feng Yang, Baoshan Township (TW); Szuya Liao, Zhubei (TW)

(21) Appl. No.: 19/261,072

(22) Filed: Jul. 7, 2025

Related U.S. Application Data
(63) Continuation of application No. 18/641,927, filed on Apr. 22, 2024.
(60) Provisional application No. 63/626,313, filed on Jan. 29, 2024.

(51) Int. Cl. H01L 23/00; H10D 30/67; H10D 84/83

(52) U.S. Cl. CPC H01L 24/80; H01L 24/74; H01L 24/08; H01L 2224/08145; H01L 2224/74; H01L 2224/80012; H01L 2224/80031; H01L 2224/80048; H01L 2224/80895; H01L 2224/80896; H01L 2224/80986; H01L 2924/40501; H01L 2924/40502; H10D 30/6735; H10D 84/83

(57) ABSTRACT

A method includes performing a cleaning process on a first surface of a first wafer, and performing a surface activation process on the first surface. The surface activation process is selected from the group consisting of: a plasma surface activation process comprising generating a plasma from a process gas, wherein ions in the plasma are removed using a filter, and wherein a remaining uncharged part of the plasma is used to treat the first surface; a laser surface activation process using a laser beam; an acid surface activation process using an acid; and an alkali surface activation process using an alkali. After the surface activation process, a rinsing process is performed on the first surface. The first surface of the first wafer is bonded to a second surface of a second wafer.

### PRIORITY CLAIM AND CROSS-REFERENCE

This application is a continuation of U.S. patent application Ser. No. 18/641,927, filed on Apr. 22, 2024, which application claims the benefit of the following provisionally filed U.S. patent application: Application No. 63/626,313, filed on Jan. 29, 2024, and entitled “Bonding Apparatus and Bonding Process,” which applications are hereby incorporated herein by reference.

### BACKGROUND

Wafer bonding processes are commonly used in the manufacturing of integrated circuits. In order to achieve wafer bonding, the surfaces of the wafers to be bonded may be activated through plasma activation processes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an apparatus for wafer bonding in accordance with some embodiments.

FIG. 2 illustrates a cleaning process using a cleaning module in accordance with some embodiments.

FIG. 3 illustrates a surface activation module comprising a plasma ion filter using metastable species in accordance with some embodiments.

FIG. 4 illustrates a top view of a plasma ion filter in accordance with some embodiments.

FIGS. 5-7 illustrate two plasma ion filters that are used in combination in accordance with some embodiments.

FIG. 8 illustrates a surface activation module comprising a plasma ion filter for filtering plasma generated from a reactive gas in accordance with some embodiments.

FIG. 9 illustrates a surface activation module comprising a plasma ion filter for generating energic molecules in accordance with some embodiments.

FIG. 10 illustrates a laser surface activation process in accordance with some embodiments.

FIG. 11 illustrates a table showing some materials and the corresponding laser wavelengths and powers used for laser surface activation processes in accordance with some embodiments.

FIG. 12 illustrates a surface activation process through spraying acid or alkali in accordance with some embodiments.

FIG. 13 illustrates a surface activation process through acid or alkali bathing in accordance with some embodiments.

FIGS. 14-17 illustrate the rinsing and alignment for bonding two wafers in accordance with some embodiments.

FIGS. 18-21 illustrate the formation of bonds for bonding two wafers in accordance with some embodiments.

FIGS. 22-26 illustrate a process for bonding two wafers in accordance with some embodiments.

FIG. 27 illustrates a process flow for bonding two wafers in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A wafer bonding process and the apparatus for performing the wafer bonding process are provided. In accordance with some embodiments of the present disclosure, the apparatus includes a surface activation module for activating the surface of the wafers to be bonded. The surface activation module is capable of avoiding the damage to the circuits of the wafers, which damage is caused by plasma, when used. The surface activation may either use a filter to filter out the ions when plasma is generated, or through an ion-free activation process such as a laser activation process, an acid activation process, an alkali activation process, or the like.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

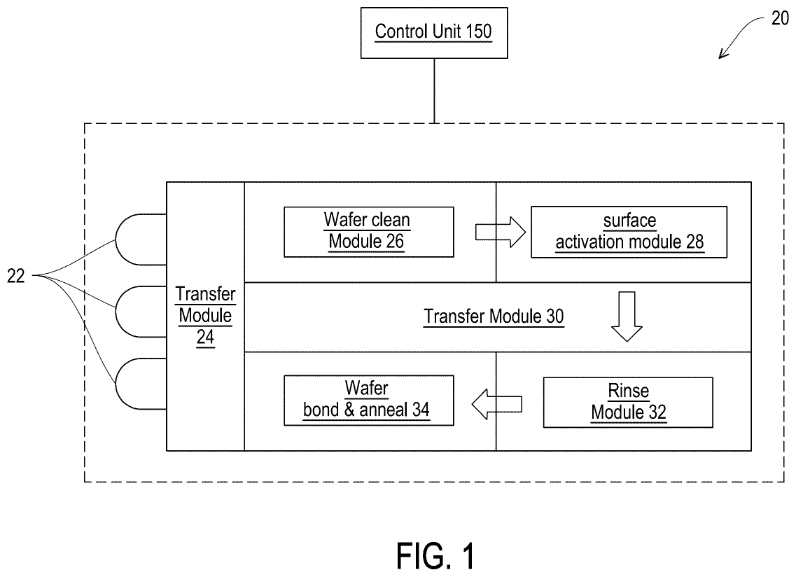

FIG. 1 illustrates a system view of an apparatus 20, which is referred to as wafer bonding module 20 in accordance with some embodiments. Wafer bonding module 20 is used for bonding wafers that may include integrated circuits in accordance with some embodiments. Wafer bonding module 20 further includes load ports 22, transfer module 24, wafer clean module 26, surface activation module 28, transfer module 30, rinse module 32, and wafer bond (pre-bond) and anneal module 34.

Load ports 22 are configured to load the wafers (that are to be bonded) into the wafer bonding module 20, and out of wafer bonding module 20 after the wafer bonding process is finished.

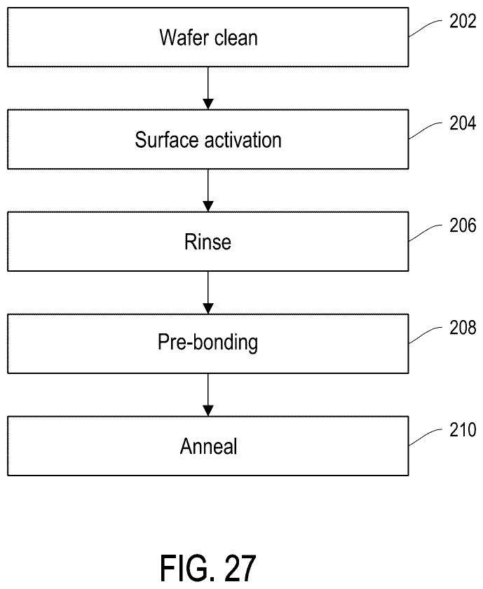

To start a wafer bonding process, the wafers to be bonded are transferred into wafer clean module 26 by transfer module 24. Wafer clean module 26 is configured to clean the surfaces of the wafers. The respective process is illustrated as process 202 in the process flow 200 as shown in FIG. 27. The cleaning process may include removing metal oxides, chemicals, particles, and the like from the surfaces of wafers.

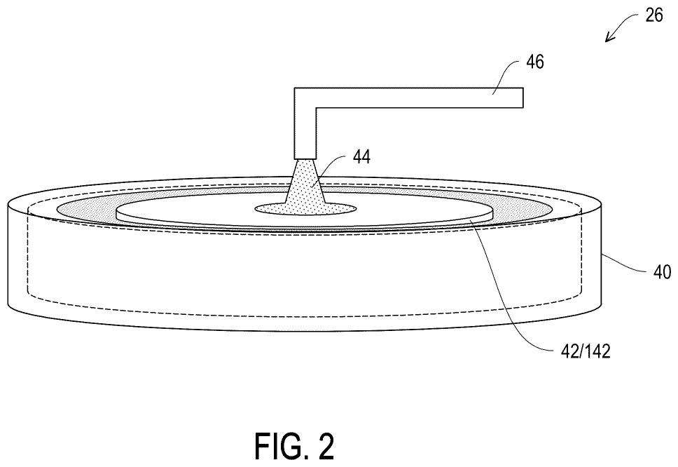

FIG. 2 illustrates a view of a part of wafer clean module 26 in accordance with some embodiments. Wafer clean module 26 may include a dispensing head 46, which is connected to a storage(s) (not shown). The storage stores a cleaning agent 44 or a plurality types of cleaning agents, which may include deionized (DI) water and a chemical(s) such as NH₃, H₂O₂, citric acid, or the like, or combinations thereof. In accordance with some embodiments, the wafer clean module 26 is configured to dispense cleaning agent 44 onto wafer 42 or 142 (referred to as 42/142 hereinafter), which is spun when the cleaning agent 44 is dispensed. The cleaning agent 44 is spun off from wafer 42/142, and is collected by wafer bathtub 40.

After a wafer 42/142 is cleaned, the wafer 42/142 is transferred into surface activation module 28, as shown in FIG. 1. A surface activation process is then performed to form dangling bonds on the surface of wafer 42/142. The respective process is illustrated as process 204 in the process flow 200 as shown in FIG. 27.

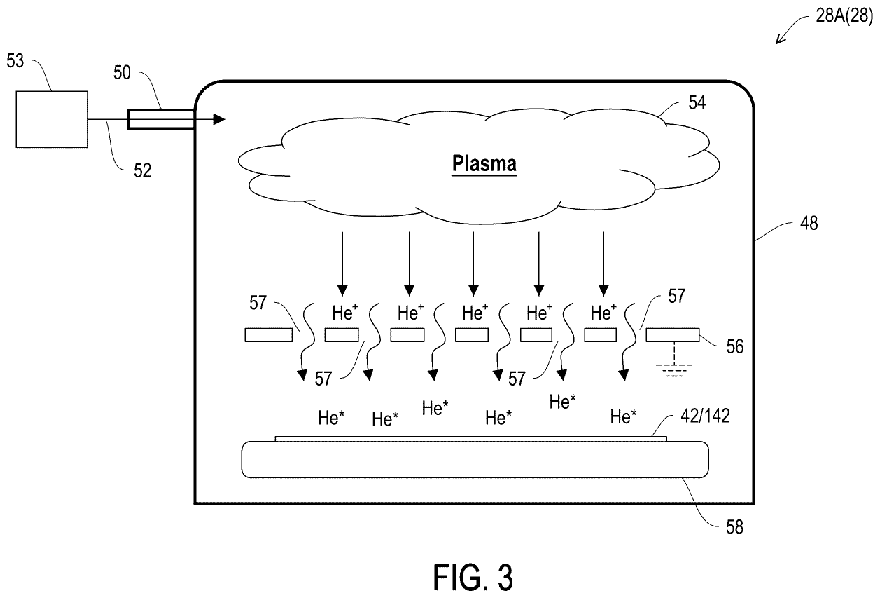

FIG. 3 illustrates a surface activation module 28A in accordance with some embodiments. Surface activation module 28A is an implementation of the surface activation module 28 in FIG. 1. Surface activation module 28A may include vacuum chamber 48, which is configured to be vacuumed. Input port 50 is connected to vacuum chamber 48, through which a process gas(es) 52 may be conducted into vacuum chamber 48. The surface activation module 28A is further configured to generate plasma from the process gas, for example, through an RF generator built therein, and through a coil (not shown) that surrounds the region in which the plasma is generated. The coil may be placed inside or outside of process chamber 48. Wafer 42/142 is placed on a wafer holder 58, which may be, for example, an E-chuck.

Plasma ion filter 56 is also built in vacuum chamber 48, and is located between wafer 42/142 and the region in which plasma is generated. In accordance with some embodiments, plasma ion filter 56 is used for filtering the ions in the generated plasma, and leaving radicals to treat wafer 42/142. In accordance with some embodiments, plasma ion filter 56 is electrically grounded. In accordance with alternative embodiments, plasma ion filter 56 is not electrically grounded and may be, for example, either electrically floating or connected to a voltage (such as a positive voltage such as 1V, 2V, 5V, 10V, or the like). Accordingly, in FIG. 3, the electrical ground connecting to plasma ion filter 56 is shown as being dashed to indicate that plasma ion filter 56 may be, or may not be, electrically grounded.

Plasma ion filter 56 may be formed of an electrically conductive material (for example, a metal) such as copper, aluminum, nickel, tungsten, or the like, a semiconductor material such as silicon, a dielectric material such as quartz, silicon oxide, silicon nitride, silicon carbide, a metal-containing dielectric such as a metal oxide (CuO, AlO, for example), a metal nitride (AlN, for example), or the like.

In accordance with some embodiments, a surface activation process is performed on wafer 42/142, during which a process gas is introduced into process chamber 48. The process gas may include an inert gas such as He, Ne, Ar, Kr, Xe, or the like, or combinations thereof. Other process gases such as N₂, O₂, and/or the like, may also be used. In the following discussion, it is assumed that He is used as the process gas, while the discussion also applies to other types of process gases.

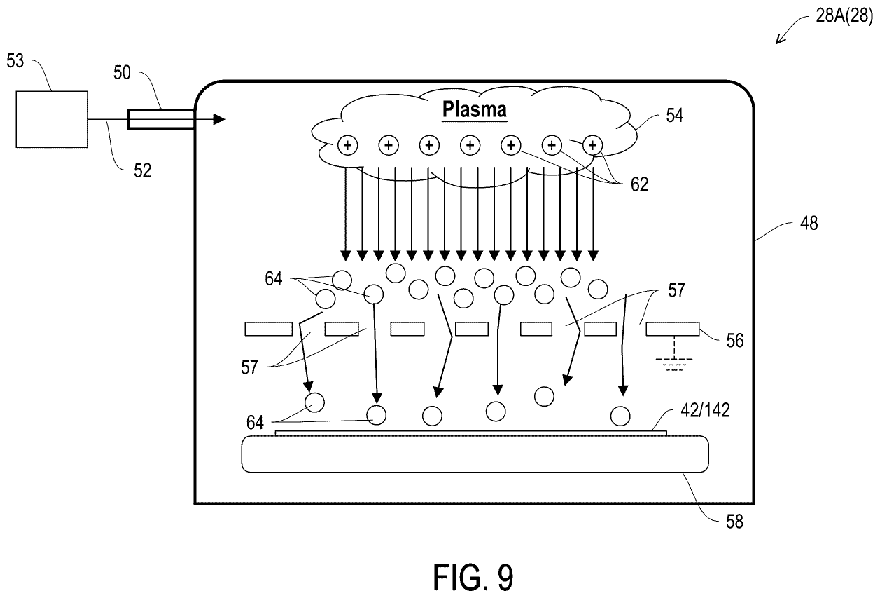

As shown in FIG. 3, plasma 54 is generated, for example, by applying a RF source power on a coil surround the location where plasma 54 is generated. The chamber pressure is controlled to be low (lower than the pressure in the embodiments in FIG. 9), for example, lower than about 1 mTorr, and may be in the range between about 0.01 mTorr and about 0.5 mTorr. Plasma 54 includes ions and radicals that are generated from the process gas. For example, plasma 54 may include radicals such as He* and ions such as He⁺ when the process gas comprises He (helium).

When plasma ion filter 56 is electrically grounded, plasma ion filter 56 attracts charges such as ions (such as He⁺) and electrons. Radicals such as He* are not charged, and may pass through openings 57 in plasma ion filter 56 to impact on wafer 42/142. When plasma ion filter 56 is not electrically grounded such as electrically floating, the nature of plasma 54 may cause an electrical field to be generated at nearby interfaces such as the surface of plasma ion filter 56. Therefore, even if plasma ion filter 56 is not electrically grounded, charges such as electrons e⁻ and ions He⁺ are still caught by plasma ion filter 56.

In accordance with some embodiments, by adjusting process conditions such as the source RF power, metastable radicals such as He* are generated. The metastable radicals He* are at high-energy states (and thus are metastable since the high-energy states are not very stable). For example, at the metastable state, radicals He* may have an energy of about 20 eV. If Ne is used as a process gas, Ne radicals at the metastable state may have an energy of about 16 eV. If Ar is used as a process gas, Ar radicals at the metastable state may have an energy of about 12 eV.

The metastable radicals, after passing through through-openings 57, will collide with the surface of wafer 42/142, release the energy, and return to a ground state. For example, the surface material of wafer 42/142 may comprise a silicon-containing material, which may comprise silicon, silicon oxide, silicon nitride, silicon carbide, silicon oxynitride, silicon oxycarbide, silicon oxy-carbo-nitride, diamond, AlN, or the like. The energy causes the breakage of the bonds of the surface material of wafer 42/142, forming dangling bonds on silicon, which enable the formation of OH bonds in subsequent rinsing process and/or when the wafer 42/142 is exposed to air (which has moisture).

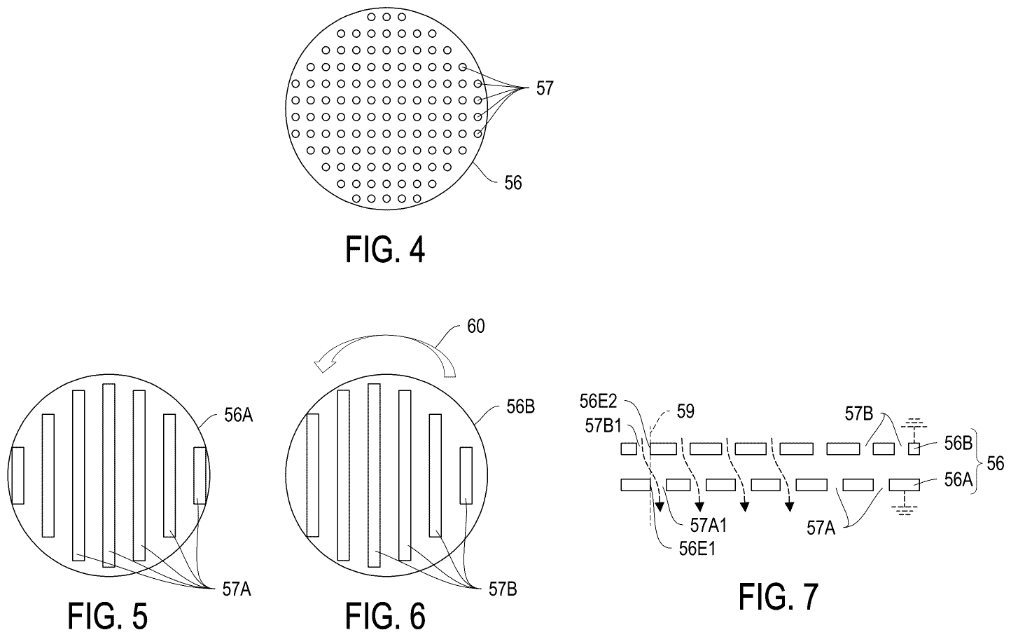

FIGS. 4 through 7 illustrate the plasma ion filter 56 in accordance with some embodiments. Referring to FIG. 4, plasma ion filter 56 may be a plate including a plurality of densely located through-opening 57 therein. The through-opening 57 may be arranged as having a repeating pattern such as an array, a beehive pattern, or the like.

FIGS. 5 and 6 illustrate two components 56A and 56B, which are collectively used as plasma ion filter 56 in accordance with alternative embodiments. Referring to FIG. 5, plasma ion filter 56A includes a plurality of elongated through-openings 57A, which are parallel to each other. Referring to FIG. 6, plasma ion filter 56B includes a plurality of elongated through-openings 57B, which are parallel to each other. When placed in vacuum chamber 48, plasma ion filter 56B is stacked over plasma ion filter 56A, as shown in FIG. 7, to form plasma ion filter 56.

In accordance with some embodiments, as shown in FIG. 7, when plasma ion filters 56A and 56B are installed in vacuum chamber 48, plasma ion filter 56A may be electrically interconnected to electrically disconnected. Either one or both of plasma ion filters 56A and 56B may be electrically floating or electrically grounded. The lengthwise directions of through-openings 57A and 57B may be parallel to each other. The through-openings 57A may be slightly offset from the respective overlying openings 57B. In accordance with some embodiments, through-openings 57A are fully offset from the underlying through-openings 57B, which means that when plasma ion filters 56A and 56B are viewed from top, the material of plasma ion filter 56A will be observed through-openings 57B, and the underlying wafer 42/142 (FIG. 3) will not be seen due to the blocking of plasma ion filter 56A.

By fully offsetting through-openings 57A from through-openings 57B, the efficiency of collecting ions will be improved, and it is less likely that ions will pass through both of through-openings 57A and 57B. For example, any ion traveling downwardly, if passing through openings 57B, will hit plasma ion filter 56A. Some radicals, on the other hand, may travel through both of openings 57B and 57A, and reach wafer 42/142.

To maximize the effect of catching ions and also maximizing the passing-through of radicals, through-openings 57A are just offset from the respective overlying nearest through-openings 57B, without offsetting more. For example, as shown in FIG. 7, plasma ion filter 56B comprises a left edge 56E2 facing an opening 57B1, and plasma ion filter 56A comprises a right edge 56E1 facing opening 57A1, wherein edges 57E1 and 57E2 are vertically aligned to the same vertical line 59.

In accordance with alternative embodiments, when plasma ion filters 56A and 56B are installed in vacuum chamber 48, the lengthwise direction of through-openings 57A may be rotated, for example, as shown by arrow 60 in FIG. 6. The rotation angle may be any angle between 0 degree and 90 degrees. When the rotation angle is 90 degrees, the lengthwise direction of openings 57A is perpendicular to the lengthwise direction of openings 57B. Accordingly, when viewing from the top of the stacked plasma ion filters 56A and 56B, the overlapping portions of openings 57A and 57B form a plurality of openings arranged as an array. This is equivalent to the openings 57 as shown in FIG. 4, except that the portions of openings 57A that do not overlap openings 57B may increase the chance of the passing-through of radicals, and the portions of openings 57B that do not overlap openings 57A may increase the chance of the passing-through of radicals.

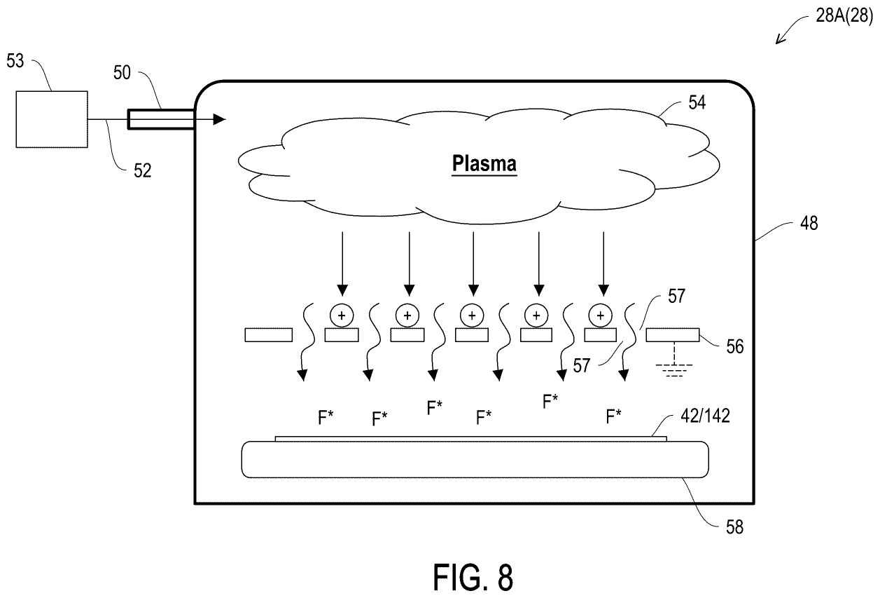

FIG. 8 illustrates the surface activation module 28A in accordance with some embodiments. The surface activation module 28A also include vacuum chamber 48, which is configured to be vacuumed. Input port 50 is connected to vacuum chamber 48, and a process gas(es) 52 may be input into vacuum chamber 48 through input port 50. In accordance with some embodiments, the input port 50 is connected to storage 53, which stores a gas(es) that is capable of etching the bond layer of wafer 42/142. When the bond layer of wafer 42/142 comprises silicon, silicon oxide, silicon nitride, silicon carbide, silicon oxynitride, silicon oxycarbide, silicon oxy-carbo-nitride, diamond, AlN, or the like, the etching gas may include a fluorine-containing etching gas such as XeF₂, BrF₃, IF₅, ClF₃, F₂, CF₄, CHF₃, CH₂F₂, CH₃F, etc., a halogen-and-carbon-containing gas such such as fluorocarbons, for example, C₄F₈, a chlorine-containing gas such as ClF₃, Cl₂, HCl, etc., or the like, or a combination of the aforementioned gases.

Plasma ion filter 56 is also built in vacuum chamber 48. In accordance with some embodiments, plasma ion filter 56 is used for filtering the ions in the generated plasma, and leaving radicals to etch wafer 42/142, which is placed in vacuum chamber 48. In accordance with some embodiments, plasma ion filter 56 is electrically grounded, electrically floating, or connected to a positive voltage. The plasma ion filter 56 may be as discussed referring to FIGS. 4 through 7 in accordance with some embodiments.

The surface activation module 28A is further configured to generate plasma from the etching gas, for example, through a RF source generator built therein. The plasma may contain the ions and the radicals of the etching gas, and electrons. For example, when the etching gas is or comprises a fluorine-containing gas, charges such as F⁺ ions and electrons, and radicals such as F* radicals are generated.

Through plasma ion filter 56, charges such as ions and electrons are filtered, and the radicals of the etching species such as F* radicals pass through the through-openings 57 of plasma ion filter 56 to impinge on the bond layer of wafer 42/142. The radicals thus etch away some of the surface material of wafer 42/142 in order to activate the surface reaction. For example, some of the silicon-containing dielectric materials are etched to generate dangling bonds, so that it is easy to form OH bonds, for example, in the subsequent rinsing process.

As will be discussed in subsequent processes, besides the gas for etching, the storage 53 may also store a non-etching gas(es) that is not used for etching wafer 42/142, and the gas is also conducted into process chamber 48 to generate plasma. In accordance with some embodiments, storage 53 storages an inert gas such as He, Ne, Ar, Kr, Xe, or the like. In accordance with some embodiments, storage 53 stores another gas that may be used for generating plasma such as O₂, N₂, H₂, or the like, or combinations thereof. The non-etching gases may also help the generation of dangling bonds through the mechanism discussed referring to FIG. 3, or the mechanism discussed referring to FIG. 9. Accordingly, in accordance with these embodiments, two mechanisms including etching and bombardment may work simultaneously to generate dangling bonds.

FIG. 9 illustrates a surface activation module 28A in accordance with some embodiments. Surface activation module 28A may include vacuum chamber 48, which is configured to be vacuumed. Input port 50 is connected to vacuum chamber 48, through which a process gas(es) 52 may be input into vacuum chamber 48. The process gas 52 may be selected from the same group of candidate gases as discussed referring to the embodiments in FIG. 3, and may include He, Ne, Ar, Kr, Xe, or the like, or combinations thereof. There may also be molecules formed of more than one atom such as N₂, O₂, H₂, and/or the like. The gas may include the combination of the above-discussed gases.

As shown in FIG. 9, plasma 54 is generated, for example, by applying a source RF power. The chamber pressure is controlled to be high, for example, higher than about 1 mTorr, and may be in the range between about 1 mTorr and about 10 Torr. Ions and radicals are generated from the process gas. Plasma 54 may include radicals such as He* and ions 62 such as He⁺, depending on the type of gases.

In accordance with some embodiments, due to the high pressure in vacuum chamber 48, the ions 62 bombard the molecules 64 such as N₂, O₂, H₂, and/or the like in the process chamber. The impacted molecules 64 are accelerated downwardly. Since the molecules 64 are not charged, the molecules may pass the through-openings 57, and collide with wafer 42/142. On the other hand, the ions 62 and electrons are still caught by plasma ion filter 56. There may also be radicals generated from the process gases, which radicals may also pass the through-openings 57, and collide with wafer 42/142.

In accordance with these embodiments, the surface material of wafer 42/142 may comprise a silicon-containing material, which may comprise silicon, silicon oxide, silicon nitride, silicon carbide, silicon oxynitride, silicon oxycarbide, silicon oxy-carbo-nitride, diamond, AlN, or the like. The kinetic energy of molecules 64 causes the breakage of the bonds of the surface material of wafer 42/142, forming dangling bonds on silicon, which enable the formation of OH bonds in subsequent rinse or exposure to moisture. Accordingly, in accordance with these embodiments, the kinetic energy of high-pressure inert gas is used to drive molecules to activate the bonding surface.

It is appreciated that the mechanism in FIGS. 3, 8, and 9 may be combined. For example, in the above-recited embodiments in FIG. 9, when inert gases are included in the process gases 52, both of a first mechanism of using metastable radicals (the mechanism discussed referring to FIG. 3), and a second mechanism of using accelerated molecules (the mechanism discussed referring to FIG. 9) may co-exist at the same time. When the chamber pressure is in a middle range such as in the range between about 0.1 mTorr and about 1 mTorr, the first mechanism and the second mechanism are balanced and have similar effect. With the reduction of the chamber pressure, the first mechanism starts to dominate until eventually the second mechanism can be ignored. With the increase in the chamber pressure, the second mechanism starts to dominate until eventually the first mechanism can be ignored.

In the embodiments as shown in FIG. 8, the mechanism of etching may also be combined with the mechanism of bombarding (FIGS. 3 and 9). For example, when inert gases are introduced into the vacuum chamber 48, the metastable radicals of the inert gases may also be generated when the chamber pressure is low to bombard the surface of wafer 42/142. Conversely or simultaneously, when the chamber pressure is high, and both of an inert gas and molecules are also introduced into chamber 48, the molecules may be accelerated to bombard the surface of wafer 42/142 in addition to the etching of wafer 42/142. As a result, more dangling bonds may be generated.

In above-discussed embodiments, plasma is generated to generate dangling bonds on the surface of wafer 42/142 through different mechanisms. Plasma ion filters 56 are used to filter the charges including ions and electrons, so that the charges will not reach wafer 42/142. If ions and electrons reach wafer 42/142, the =charges may damage the devices in wafer 42/142, which effect is referred to as plasma induced damage. For example, the charges may flow to, and are collected by, the gate dielectrics of transistors through the metal interconnect structure in wafer 42/142, and the charges may damage the gate dielectrics. In accordance with some embodiments of the present disclosure, since the charges are filtered and will not reach the wafer that is activated by the plasma activation process, the damage is avoided.

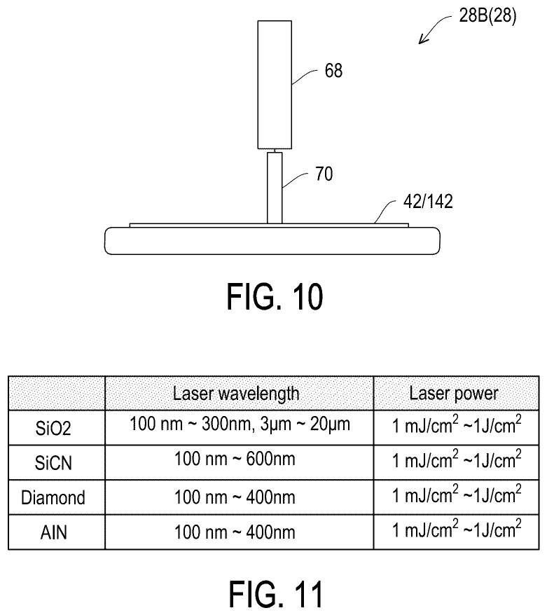

FIG. 10 illustrates a surface activation module 28B in accordance with alternative embodiments. The surface activation module 28B implements the surface activation module 28 as shown in FIG. 1 in accordance with these embodiments. The surface activation module 28B includes a laser module 68, which includes a laser beam generator and a laser beam projector for projecting the generated laser beam 70 onto wafer 42/142.

In accordance with some embodiments, the laser module 68 scans through wafer 42/142 line by line using laser beam 70. In accordance with alternative embodiments, the projection area of laser beam is magnified to cover an entire wafer 42/142 or a portion of wafer 42/142. The laser beam 70 is projected to the intended area of wafer 42/142, until the projected wafer 42/142 is activated and dangling bonds have been generated. The laser beam 70 is then moved to another area of wafer 42/142 (when the projection area is a portion, not an entirety, of wafer 42/142) to perform the activation. This process is repeated until all of the wafer 42/142 has been projected by laser beam 70 and activated. When the laser beam 70 is projected to an entirety of wafer 42/142, the projection is performed until the intended activation is achieved. The laser energy causes the breakage of the bonds on the bond layer, enabling the formation of OH bonds.

In order to adequately activate the surface of wafer 42/142, the laser beam 70 may need to be in certain wavelength range and have certain power density. The wavelength range and the required power density are also related to the surface material of wafer 42/142 to be activated. FIG. 11 illustrates a table showing some materials, the corresponding wavelength ranges, and the corresponding power densities in accordance with some embodiments.

In accordance with some embodiments, when the surface layer (for example, layers 94 or 194 in FIG. 23) comprises silicon oxide, the wavelength may be in the range between about 100 nm and about 300 nm, or in the range between about 3 μm and about 20 μm. When the surface layer comprises SiCN, the wavelength may be in the range between about 100 nm and about 600 nm. When the surface layer comprises diamond, the wavelength may be in the range between about 100 nm and about 400 nm. When the surface layer comprises AlN, the wavelength may be in the range between about 100 nm and about 400 nm.

The power density of the laser beam 70 also needs to be in certain range. When the power density is too high, the wafer 42/142 may be damaged. When the power density is too low, the surface of wafer 42/142 may not be adequately activated. In accordance with some embodiments, when the surface layer comprises silicon oxide, SiCN, diamond, or AlN, the power density may be in the range between about 1 mJ/cm² and about 1 J/cm². Since the laser activation does not involve plasma, the plasma induced damage is avoided.

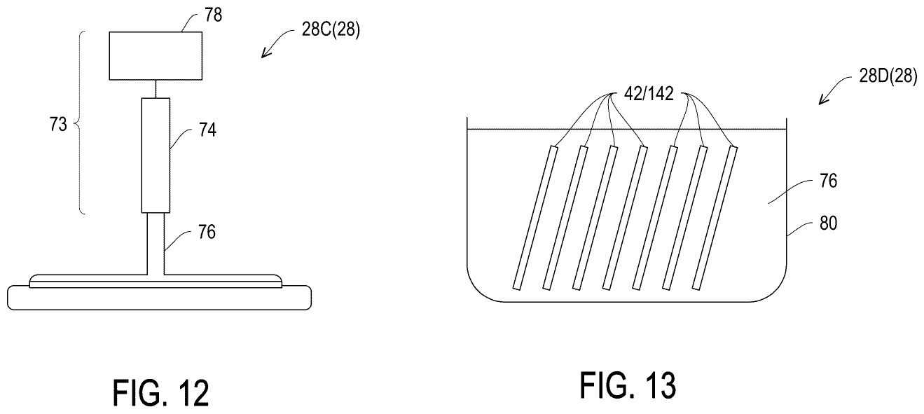

FIG. 12 illustrates a surface activation module 28C in accordance with some embodiments. The surface activation module 28C implements the surface activation module 28 as shown in FIG. 1 in accordance with these embodiments. The surface activation module 28C includes a wet surface activation module 73, which includes a sprayer 74, and a storage 78 for storing the activation solution 76. The sprayer 74 is configured to spray activation solution 76 on wafer 42/142.

In accordance with some embodiments, activation solution 76 is an acid, which may have a pH value in the range between about 1 and about 6. For example, activation solution 76 may comprise the solution of carbon dioxide (CO₂). The surface activation process may include spraying the activation solution 76 on wafer 42/142 for a period of time in the range between about 1 minute and about 2 hours. As a result of the spraying, the acid breaks the bonds at the surface of wafer 42/142, and thus dangling bonds are generated. Since the activation using the acid solution does not involve plasma, no plasma induced damage is resulted.

In accordance with alternative embodiments, activation solution 76 is an alkali, which may have a pH value greater than 7, and may be in the range between about 8 and about 12. For example, activation solution 76 may comprise the solution of ammonia (NH₃), and thus comprises NH₄OH. The surface activation process may include spraying the activation solution 76 on wafer 42/142 for a period of time in the range between about 1 minute and about 2 hours. As a result of the spraying, the alkali breaks the bonds at the surface of wafer 42/142, and thus generate dangling bonds. Since the activation using the alkali solution does not involve plasma, no plasma induced damage is resulted.

FIG. 13 illustrates a surface activation module 28D in accordance with some embodiments. The surface activation module 28D implements the surface activation module 28 as shown in FIG. 1 in accordance with these embodiments. The surface activation module 28D includes an activation solution tank 80, which stores wet surface activation solution 76 therein. Wafers 42 and/or 142 (which are also referred to as wafers 42/142) are submerged and soaked in activation solution 76, so that the surfaces of wafers 42/142 are activated.

The wet surface activation solution 76 may be selected from the same group of candidate solutions 76 discussed referring to the embodiments shown in FIG. 12, and may include an acid, an alkali, or the like, which have the pH value as discussed. In accordance with some embodiments, the activation process includes submerging wafers 42/142 in activation solution 76 for a period of time in the range between about 1 minute and about 2 hours. As a result of the wafer submerging in acid or alkali, the acid or alkali breaks the bonds at the surface of wafer 42/142, and thus dangling bonds are generated. Since the activation by submerging the wafers in acid or alkali does not involve plasma, no plasma induced damage is resulted.

In accordance with some embodiments, after the spraying or submerging of wafer 42/142 in acid or alkali, wafer 42/142 is rinsed using DI water, so that the residue acid or alkali is removed from wafer 42/142. The rinsing may be performed in activation module.

In accordance with some embodiments, the surface activation module 28 includes a single one of the activation modules 28A, 28B, 28C, and 28D. In accordance with alternative embodiments, the surface activation module 28 includes two or more of the activation modules 28A, 28B, 28C, and 28D. Two or more surface activation processes may thus be performed to improve the activation.

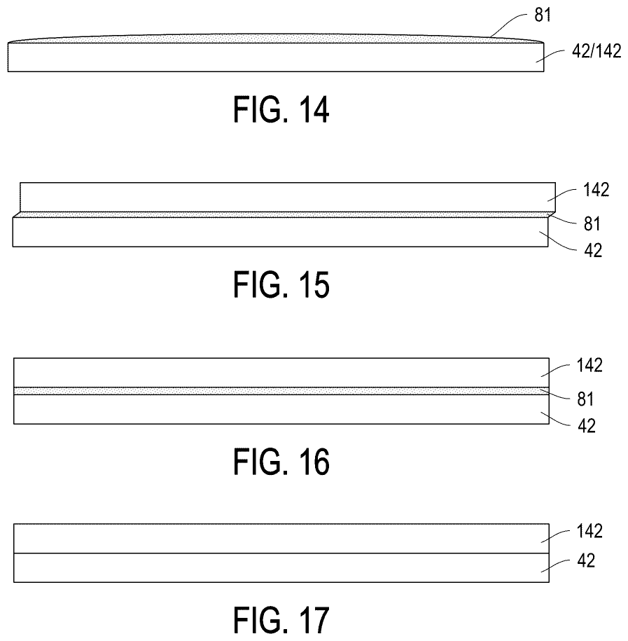

Referring back to FIG. 1, after the surface activation process 28, which is discussed referring to FIGS. 3 through 13, the activated wafers 42/142 are transferred by transfer module 30 into rinse module 32, in which a rinsing process is performed. The respective process is illustrated as process 206 in the process flow 200 as shown in FIG. 27. FIG. 14 illustrates wafer 42/142 that has been surface activated. In order to provide a sufficient H₂O between wafers to improve the subsequent wafer bonding, wafer 42/142 may be soaked in water. Alternatively, water may be dispensed on the bonding surface of wafer 42/142 using a water sprayer. The relative humidity in the bonding area is controlled to be in a range between about 20% and about 70% for providing a sufficient amount of water to form hydrogen bonds and create linkage between the wafers. The water 81 is shown on the surface of wafer 42/142.

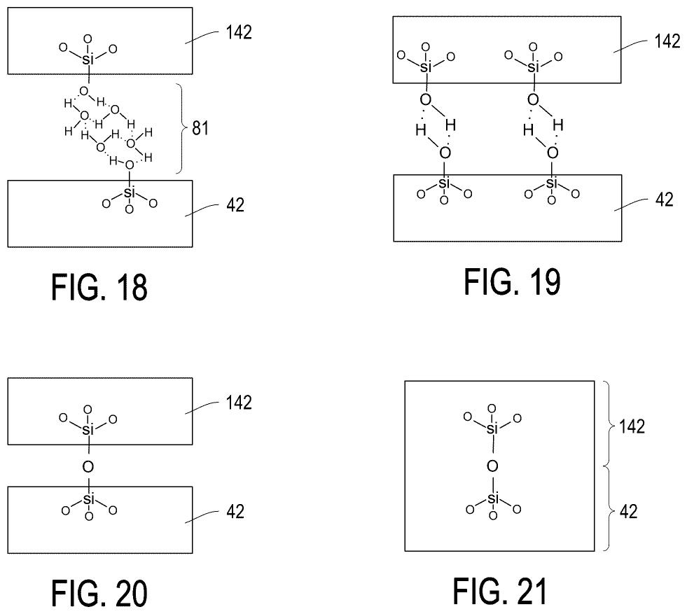

In the rinsing process, water (H₂O) reacts with the dangling bonds at the surface of wafer 42/142, which dangling bonds are generated by the surface activation process. High-density Si—OH bonds are thus formed, which OH bonds are shown in FIG. 18.

FIG. 15 illustrates a coarse pre-alignment process of wafer 142 to wafer 42. The misalignment value may be greater than about 200 μm. Next, as shown in FIG. 16, a fine alignment process is performed, until the misalignment value is reduced to around 400 nm or smaller. In a subsequent process, an anneal process is performed, so that the water 81 between wafers 42 and 142 is evaporated, and Si—O—Si bonds are formed to bond wafer 42 and 142, as shown in FIG. 17.

FIGS. 18-21 illustrate the stages and the chemical structure between wafers 42 and 142 in accordance with some embodiments. In FIG. 18, wafer 142 is pre-bonded to wafer 42 (also shown in FIGS. 15 and 16). The respective process is illustrated as process 208 in the process flow 200 as shown in FIG. 27. The water 81 as shown in FIG. 16 is illustrated in FIG. 18. In the pre-bonding, a force is applied to the center of wafer 142, so that the center of wafer 142 is put into contact with the center of wafer 42. The contact propagates from the center to the edges of wafers 142 and 42, and a bond wave is generated and propagated. With the bond wave being propagated, the air and moisture between wafers 142 and 42 are squeezed out. The resulting structure is shown schematically as shown in FIG. 19, wherein the OH bonds at the surface of wafer 142 are closely located with the OH bonds at the surface of wafer 42.

An annealing process is then performed, for example, at a temperature in the range between about 150° C. and about 200° C. The respective process is illustrated as process 210 in the process flow 200 as shown in FIG. 27. The annealing time may be in the range between about 1 hour and 2.5 hours. During the annealing, H₂O is formed due to the breaking of OH bonds, and due to the reaction of the OH bonds with the H atom breaking from OH bonds. The O atom, which is bonded to a Si atom, is bonded to another oxygen atom that is generated due to the breaking of the OH bond. Si—O—Si bonds are thus formed. Eventually, wafers 142 and 42 are bonded together, as shown in FIGS. 20 and 21.

Referring back to FIG. 1, wafer bonding module 20 includes control unit 150, which is connected to, and controls the operation of all of the processes as discussed above, including the operations of wafer clean module 26, the surface activation module 28, the transfer modules 24 and 30, the rinse module 32, and the pre-bonding and annealing module 34.

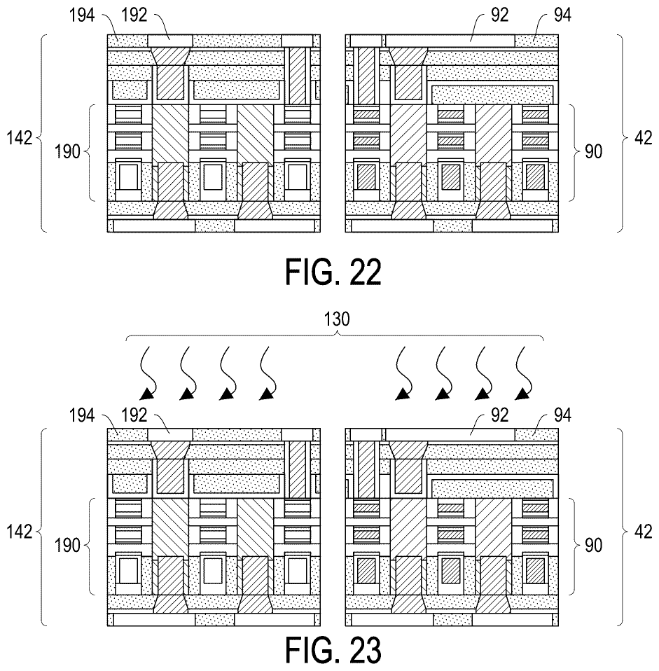

FIGS. 22-26 illustrate the views of intermediate stages in the bonding of wafers in accordance with some embodiments, in which wafers 42 and 142 comprise Gate-All-Around (GAA) transistors, and hybrid bonding is performed. Referring to FIG. 22, wafer 42 includes GAA transistor 90. Bond pads 92 and bond layer 94 are formed on the surface of wafer 42. Wafer 142 includes GAA transistor 190. Bond pads 192 and bond layer 194 are formed on the surface of wafer 142.

Next, as shown in FIG. 23, surface activation process 130 is performed on wafers 42 and 142. The surface activation process 130 is performed using surface activation module 28 as shown in FIG. 1, which may be either one of the activation modules 28A-28D as shown in FIGS. 3-13. The surface activation process 130 results in dangling bonds to be generated on the surfaces of bond layers 94 and 194.

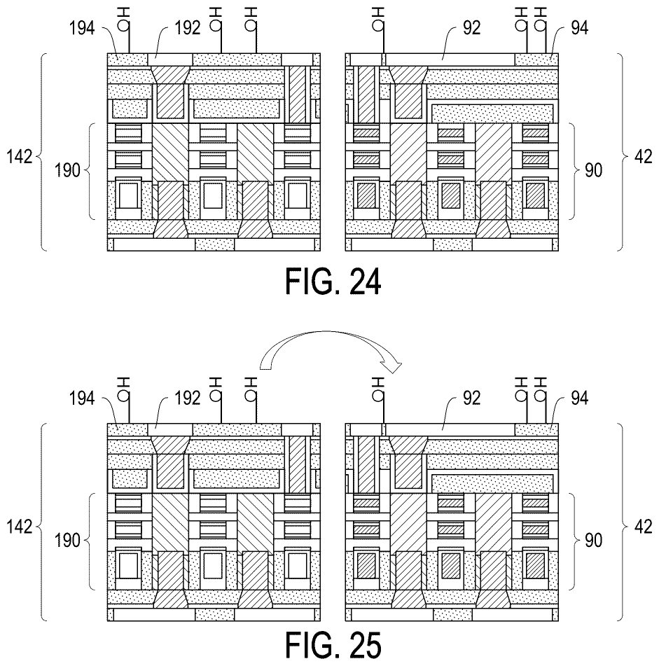

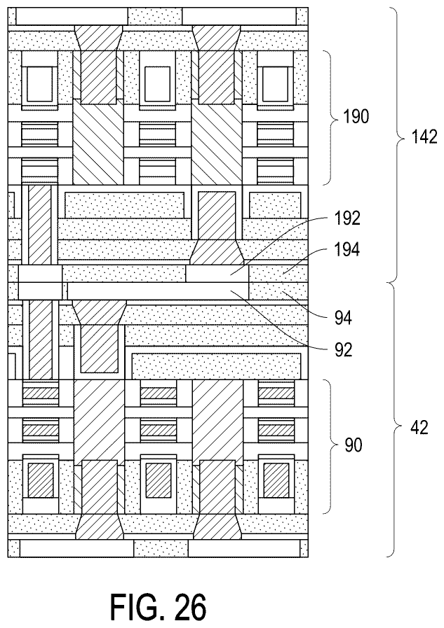

After a subsequent rinsing process, high-density OH bonds are formed on the surfaces of wafers 42 and 142, as shown in FIG. 24. Wafer 142 is then placed over wafer 42, as shown in FIG. 25. Wafer 142 is then bonded to wafer 42 through pre-bonding and annealing. The resulting bonded wafers are shown in FIG. 26.

The embodiments of the present disclosure have some advantageous features. By performing an activation process without allowing plasma to be in contact with the wafer, no plasma induced damage is resulted. The activation process may involve filtered plasma, a laser beam, or spraying or bathing process using an acid or an alkali.

In accordance with some embodiments of the present disclosure, a method comprises performing a cleaning process on a first surface of a first wafer; performing a surface activation process on the first surface, wherein the surface activation process is selected from the group consisting of a plasma surface activation process comprising generating a plasma from a process gas, wherein ions in the plasma are removed using a filter, and wherein a remaining uncharged part of the plasma is used to treat the first surface; a laser surface activation process using a laser beam; an acid surface activation process using an acid; and an alkali surface activation process using an alkali; after the surface activation process, performing a rinsing process on the first surface; and bonding the first surface of the first wafer to a second surface of a second wafer.

In an embodiment, the surface activation process comprises the plasma surface activation process, and wherein the ions in the plasma are filtered using the filter comprising a plurality of openings. In an embodiment, the filter that is electrically grounded is used to remove the ions. In an embodiment, the filter that is electrically floating is used to remove the ions. In an embodiment, radicals are left in the plasma that is filtered, and the radicals are used to treat the first wafer. In an embodiment, ions in the plasma are used to collide molecules in the process gas and to accelerate the molecules, and the molecules that are accelerated pass through openings in the filter to reach the first wafer.

In an embodiment, the process gas comprises an etching gas, and wherein radicals left in the plasma are used to etch the first wafer. In an embodiment, the etching gas comprises fluorine, and wherein the radicals left in the plasma comprises fluorine radicals. In an embodiment, the surface activation process comprises the laser surface activation process, and the laser surface activation process comprises using the laser beam to project on the first surface of the first wafer. In an embodiment, the surface activation process comprises the acid surface activation process, and wherein the acid surface activation process comprises using the acid to etch a surface portion of the first wafer.

In an embodiment, the acid surface activation process comprises spraying the first surface of the first wafer using a solution of the acid. In an embodiment, the acid surface activation process comprises soaking the first wafer using a solution of the acid. In an embodiment, the surface activation process comprises the alkali surface activation process, and wherein the alkali surface activation process comprises spraying the first surface of the first wafer using a solution of the alkali.

In accordance with some embodiments of the present disclosure, a method comprises generating a plasma from a process gas; using a filter to remove charged particles from the plasma; performing a surface activation process on a first wafer using uncharged parts in a remaining portion of the plasma; after the surface activation process, performing a rinsing process on the first wafer; and bonding the first wafer to a second wafer.

In an embodiment, the uncharged parts used for the surface activation process comprise radicals, and wherein the first wafer is etched by the radicals. In an embodiment, the uncharged parts comprise metastable radicals, and the metastable radicals release energy to the first wafer. In an embodiment, the uncharged parts used for the surface activation process comprise molecules that are accelerated by ions in the plasma.

In accordance with some embodiments of the present disclosure, a method comprises placing a first wafer into a process chamber; conducting a process gas into the process chamber; generating a plasma from the process gas, wherein a filter is located between the first wafer and the plasma, and wherein uncharged parts of the plasma pass through the filter to reach the first wafer; and bonding the first wafer to a second wafer. In an embodiment, the process gas comprises an etching gas. In an embodiment, the process gas further comprises an inert gas selected from the group consisting of He, Ne, Ar, Kr, Xe, and combinations thereof.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
performing a cleaning process on a first surface of a first wafer;
performing a surface activation process on the first surface, wherein the surface activation process is selected from the group consisting of:
a plasma surface activation process comprising generating a plasma from a process gas, wherein ions in the plasma are removed using a filter, and wherein a remaining uncharged part of the plasma is used to treat the first surface;
a laser surface activation process using a laser beam;
an acid surface activation process using an acid; and
an alkali surface activation process using an alkali;
after the surface activation process, performing a rinsing process on the first surface; and
bonding the first surface of the first wafer to a second surface of a second wafer,
wherein the surface activation process comprises the plasma surface activation process,
wherein the ions in the plasma are filtered using the filter comprising a plurality of openings, and
wherein ions in the plasma are used to collide molecules in the process gas and to accelerate the molecules, and the molecules that are accelerated pass through openings in the filter to reach the first wafer.
